(19) United States
(12) Patent Application Publication
(10) Pub. No.: US 2026/0059971 A1
(43) Pub. Date: Feb. 26, 2026

(54) DISPLAY DEVICE

(71) Applicant: LG Display Co., Ltd., Seoul (KR)

(72) Inventors: Jinhyeon KIM, Paju-si (KR); Kangil KIM, Paju-si (KR); Pureum KIM, Paju-si (KR)

(73) Assignee: LG Display Co., Ltd., Seoul (KR)

(21) Appl. No.: 19/194,841

(22) Filed: Apr. 30, 2025

(30) Foreign Application Priority Data
Aug. 23, 2024 (KR) 10-2024-0113354

(51) Int. Cl. H10K 59/80; H10K 59/122

(52) U.S. Cl. CPC H10K 59/80518; H10K 59/122; H10K 59/80516

(57) ABSTRACT

A display device according to an example includes a substrate having an emissive area and a non-emissive area, a reflective electrode on the substrate, an auxiliary layer on the reflective electrode, and an organic light-emitting element on the reflective electrode and the auxiliary layer. The auxiliary layer is disposed in the non-emissive area.

### CROSS-REFERENCE TO RELATED APPLICATION

The present application claims priority to Korean Patent Application No. 10-2024-0113354, filed in the Republic of Korea on Aug. 23, 2024, the entire contents of which is hereby expressly incorporated by reference into the present application.

### BACKGROUND OF THE DISCLOSURE

### Technical Field

This specification relates to a display device.

### Description of the Related Art

With the advancement of the information society, there is an increasing demand for display devices that can show images, and various types of display devices such as liquid crystal display (LCD) devices and organic light emitting diode (OLED) displays are being utilized.

Among such display devices, OLED displays are self-emissive, offering superior viewing angles and contrast ratios compared to LCD devices, while eliminating a need for a separate backlight. The OLED displays provide a lightweight and slim design with advantageous power consumption. Furthermore, the OLED displays support low-voltage direct current (DC) operation, feature fast response times, and, most notably, offer the advantage of lower manufacturing costs.

Recently, there has been a growing demand for OLED displays that cater to the needs of augmented reality (AR), virtual reality (VR), and ultra-high-resolution display devices of comparable quality.

### SUMMARY OF THE DISCLOSURE

It is an object of this disclosure to provide a display device capable of improving the color deviation of light emitted through a bank in a non-emissive area.

It is another object of this disclosure to provide a display device capable of shielding light emitted through a bank in a non-emissive area.

The objects of this disclosure are not limited to the aforementioned, and other technical objectives can be inferred from the following embodiments.

In order to accomplish the above objects, a display device according to one or more embodiments of this disclosure includes a substrate including an emissive area and a non-emissive area surrounding the emissive area, a reflective electrode on the substrate, an auxiliary layer on the reflective electrode, and an organic light-emitting element on the reflective electrode and the auxiliary layer, wherein the auxiliary layer is disposed in the non-emissive area.

The specific details of other embodiments are included in the detailed description and drawings.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display device according to one or more embodiments of the present disclosure;

FIG. 2 is an example of a cross-sectional view taken along line A-A′ of FIG. 1;

FIG. 3 is an example of a cross-sectional view taken along line B-B′ of FIG. 1;

FIG. 4 is an example of a cross-sectional view of the organic light-emitting element according to FIG. 2;

FIG. 5 is a cross-sectional view of an alternative example of the organic light-emitting element according to FIG. 2;

FIG. 6 is an example of an enlarged cross-sectional view of Q1 area in FIG. 2;

FIG. 7 is a cross-sectional view of a display device according to another embodiment of the present disclosure;

FIG. 8 is a cross-sectional view of a display device according to another embodiment of the present disclosure;

FIG. 9 is a cross-sectional view of a display device according to another embodiment of the present disclosure;

FIG. 10 is a cross-sectional view of a display device according to another embodiment of the present disclosure; and

FIG. 11 is a cross-sectional view of a display device according to another embodiment of the present disclosure.

### DETAILED DESCRIPTION OF THE EMBODIMENTS

Hereinafter, various embodiments of the present disclosure are described with reference to accompanying drawings. In the specification, when a component (or area, layer, part, etc.) is mentioned as being “on top of,” “connected to,” or “coupled to” another component, it can mean that it can be directly connected/coupled to the other component, or a third component can be placed between them.

The same reference numerals refer to the same components. In addition, in the drawings, the thickness, proportions, and dimensions of the components are exaggerated for effective description of the technical content. The expression “and/or” is taken to include one or more combinations that can be defined by associated components.

The terms “first,” “second,” etc. are used to describe various components, but the components should not be limited by these terms. The terms are used only for distinguishing one component from another component and may not define order or sequence. For example, a first component can be referred to as a second component and, similarly, the second component can be referred to as the first component, without departing from the scope of the embodiments. The singular forms are intended to include the plural forms as well unless the context clearly indicates otherwise.

The terms such as “below,” “lower,” “above,” “upper,” etc. are used to describe the relationship of components depicted in the drawings. The terms are relative concepts and are described based on the direction indicated on the drawing.

It will be further understood that the terms “comprises,” “has,” “includes,” and the like are intended to specify the presence of stated features, numbers, steps, operations, components, parts, or a combination thereof but are not intended to preclude the presence or possibility of one or more other features, numbers, steps, operations, components, parts, or combinations thereof.

Features of various embodiments of the present disclosure can be partially or entirely coupled to or combined with each other and can be operated, linked, or driven together in various ways. Embodiments of the present disclosure can be carried out independently from each other, or can be carried out together in co-dependent or related relationship.

Further, the term “can” encompasses all the meanings and coverages of the term “may” and vice versa.

All the components of each display device or apparatus according to all embodiments of the present disclosure are operatively coupled and configured.

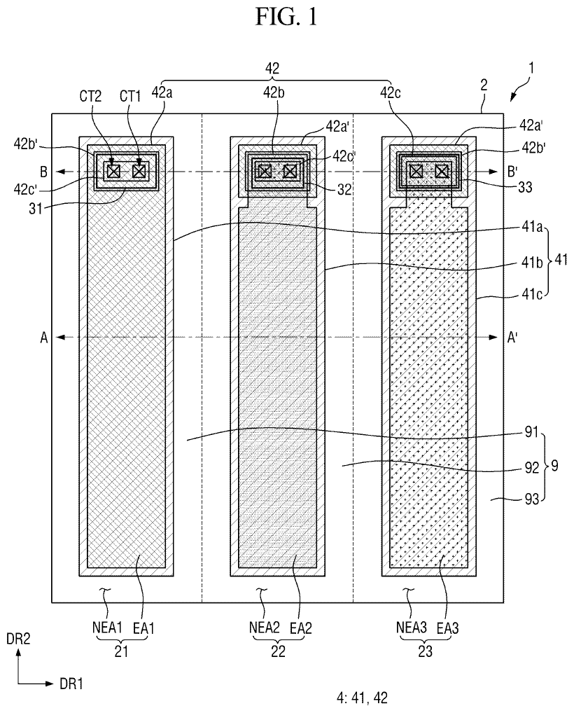

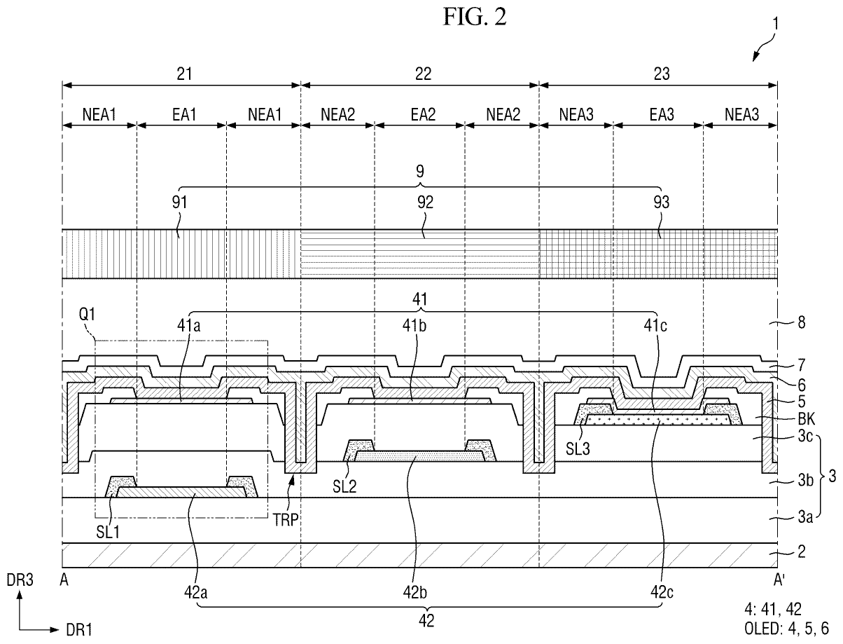

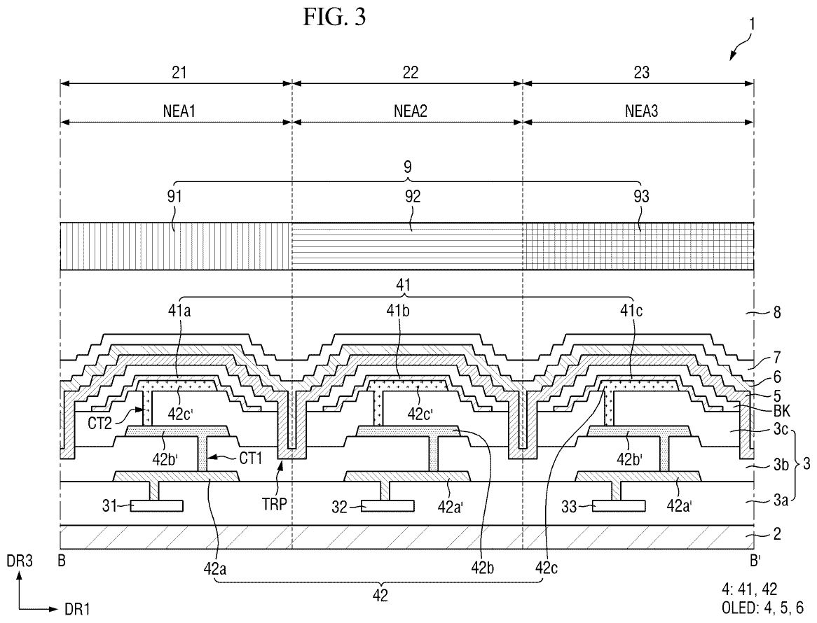

FIG. 1 is a plan view of a display apparatus according to one or more embodiments of the present disclosure. FIG. 2 is a cross-sectional view taken along line A-A′ of FIG. 1. FIG. 3 is a cross-sectional view taken along line B-B′ of FIG. 1.

Referring to FIGS. 1 to 3, a display device 1 according to one or more embodiments includes a substrate 2, a first electrode 4, a common light-emitting layer 5, and a cathode electrode 6.

A plurality of sub-pixels 21, 22, and 23 are formed on the substrate 2. The plurality of sub-pixels 21, 22, and 23 can form a single pixel. A plurality of pixels can be formed on the substrate 2.

The plurality of sub-pixels 21, 22, and 23 includes the first sub-pixel 21, the second sub-pixel 22, and the third sub-pixel 23. The first subpixel 21, second subpixel 22, and third subpixel 23 are arranged in order, such that one side of the first subpixel 21, for example, the right side, is adjacent to the second subpixel 22, and one side of the second subpixel 22, for example, the right side, is adjacent to the third subpixel 23.

Throughout this specification, the phrase “two sub-pixels are arranged adjacent to each other” or the like should be interpreted to mean that no other sub-pixel is placed between the two sub-pixels.

The first sub-pixel 21 can be configured to emit red (R) light, the second sub-pixel 22 can be configured to emit green (G) light, and the third sub-pixel 23 can be configured to emit blue (B) light, although this is not necessarily limited to these colors.

In FIG. 1, the pixel is shown as including only three sub-pixels 21, 22, and 23, but it is not limited to this configuration, and the pixel can include four sub-pixels. When the pixel includes four sub-pixels, a fourth sub-pixel configured to emit white (W) light can be further included.

The first to third sub-pixels 21, 22, and 23 can each be configured with the same size. For example, the first to third sub-pixels 21, 22, and 23 can each be configured to have the same width and height. Here, the width can refer to the horizontal direction (e.g., first direction DR1) based on FIG. 1, and the height can refer to the direction perpendicular to the width (e.g., second direction DR2) based on FIG. 1, though the embodiments of this disclosure are not limited thereto.

Each of the sub-pixels 21, 22, and 23 can include its corresponding emissive area EA1, EA2, or EA3 and non-emissive area NEA1, NEA2, or NEA3. The first sub-pixel 21 can include a first emissive area EA1 and a first non-emissive area NEAL surrounding the first emissive area EA1, the second sub-pixel 22 can include a second emissive area EA2 and a second non-emissive area NEA2 surrounding the second emissive area EA2, and the third sub-pixel 23 can include a third emissive area EA3 and a third non-emissive area NEA3 surrounding the third emissive area EA3. The emissive areas EA1, EA2, and EA3 can be the same as the areas exposed from the bank BK of the anode electrodes 41a, 41b, and 41c, which will be described later.

The first electrode 4 is patterned for each individual panel sub-pixel 21, 22, and 23. For example, a single first electrode 4 is formed in the first sub-pixel 21, another first electrode 4 is formed in the second sub-pixel 22, and yet another first electrode 4 is formed in the third sub-pixel 23. The first electrode 4 can function as the anode of the display device 1. The first electrode 4 can include a reflective electrode and an anode electrode. The anode electrode 41 and the reflective electrode 42 can be disposed for each sub-pixel 21, 22, and 23. The anode electrode 41 includes a first anode electrode 41a disposed in the first sub-pixel 21, a second anode electrode 41b disposed in the second sub-pixel 22, and a third anode electrode 41c disposed in the third sub-pixel 23, while the reflective electrode 42 can include a first reflective electrode 42a disposed in the first sub-pixel 21, a second reflective electrode 42b disposed in the second sub-pixel 22, and a third reflective electrode 42c disposed in the third sub-pixel 23.

A bank BK (e.g., in FIG. 2), which will be described later, can be disposed on each anode electrode 41a, 41b, and 41c. The bank BK can be configured to cover the edges of the anode electrodes 41a, 41b, and 41c disposed in the first to third sub-pixels 21, 22, and 23, thereby distinguishing the first sub-pixel 21, the second sub-pixel 22, and the third sub-pixel 23.

The display device 1 includes reflective electrodes 42a, 42b, and 42c with different surface heights for the respective sub-pixels 21, 22, and 23, thereby further improving light extraction efficiency by utilizing microcavity characteristics.

The microcavity characteristic refers to the phenomenon where, when the distance between the reflective electrodes 42a, 42b, and 42c and the cathode electrode 6 is an integer multiple of half the wavelength (λ/2) of the light emitted from the sub-pixels 21, 22, and 23, constructive interference occurs, amplifying the light, and the repeated reflection and re-reflection process between the reflective electrodes 42a, 42b, and 42c and the cathode electrode 6 continuously increases the amplification, thereby improving the external light extraction efficiency.

The common light-emitting layer 5 can be configured to emit white light. For example, the common light-emitting layer 5 can be configured as a 2-stack structure including a blue light-emitting layer, a yellow-green light-emitting layer, and a charge generation layer, or as a 3-stack structure including a blue light-emitting layer, a green light-emitting layer, a red light-emitting layer, and a charge generation layer to emit white light, but is not limited to these configurations and can be provided with a plurality of layers exceeding three stacks as possible as it is capable of emitting white light.

The common light-emitting layer 5 can be formed as a common layer extending across the entire first to third panel sub-pixels 21, 22, and 23.

The cathode electrode 6 is used to form an electric field with the anode electrodes 41a, 41b, and 41c and can function as a cathode. The cathode electrode 6 is disposed on the upper surface of the common light-emitting layer 5, opposite to the lower surface where the anode electrodes 41a, 41b, and 41c are in contact, and can be provided as a common layer across the entire first to third sub-pixels 21, 22, and 23.

In the case of a top emission configuration, the cathode electrode 6 can be provided as a second electrode, but in the case of a bottom emission method, it can be provided as a first electrode including a reflective material. In the case of a top emission configuration, the cathode electrode 6 can be formed as a semi-transparent electrode to enhance light extraction efficiency using microcavity characteristics. The display device 1 utilizes microcavity characteristics in the top emission configuration to improve light extraction efficiency, which is why the cathode electrode 6 is formed as a semi-transparent electrode, as an example.

The color filter layer 9 is provided on each of the first to third sub-pixels 21, 22, and 23 to block predetermined colors from the light emitted by the common light-emitting layer 5 of each sub-pixel 21, 22, and 23. The first color filter 91 provided in the first sub-pixel 21 can be configured to block all colors except for red (R) light. In this case, the first color filter 91 can be a red color filter. The second color filter 92 provided in the second sub-pixel 22 can be configured to block all colors except for green (G) light. In this case, the second color filter 92 can be a green color filter. The third color filter 93 provided in the third sub-pixel 23 can be configured to block all colors except for blue (B) light. In this case, the third color filter 93 can be a blue color filter. However, the embodiments of this disclosure are not limited thereto.

The first to third color filters 91, 92, and 93 provided in each of the first to third sub-pixels 21, 22, and 23 can be configured to have the same size as the respective sub-pixels or can be scaled up or down by a certain ratio of the size of each sub-pixel.

Transistors 31, 32, and 33 can be disposed in the non-emissive areas NEA1, NEA2, and NEA3 of each sub-pixel 21, 22, and 23, respectively. For example, transistors 31, 32, and 33 can overlap with the reflective electrodes 42a, 42b, and 42c disposed in each sub-pixel 21, 22, and 23. Transistors 31, 32, and 33 can be electrically connected to the reflective electrodes 42a, 42b, and 42c.

Hereinafter, a detailed description of the laminated structure of the display device 1 according to an embodiment of the present disclosure is provided.

The display device 1 according to an embodiment includes a substrate 2, an insulating layer 3, a first electrode 4, a bank BK, a common light-emitting layer 5, a cathode electrode 6, a capping layer 7, an encapsulation layer 8, and a color filter layer 9.

The substrate 2 can be made of a semiconductor material such as plastic film, glass substrate, or silicon.

The substrate 2 can be made of transparent or opaque materials. Sub-pixels 21, 22, and 23 are provided on the substrate 2. The first sub-pixel 21 can emit red (R) light, the second sub-pixel 22 can emit blue (B) light, and the third sub-pixel 23 can emit green (G) light.

In an embodiment, the display device 1 is configured in a so-called top emission method where the emitted light is released upwards, and therefore, the material of the substrate 100 can be either a transparent material or an opaque material. On the upper side of the first to third sub-pixels 21, 22, and 23), color filters 91, 92, and 93 can be provided to transmit light of the respective colors as mentioned above.

The insulating layer 3 is formed on the substrate 2. The insulating layer 3 can include an inorganic insulating material. The insulating layer 3 can include a first insulating layer 3a, a second insulating layer 3b on the first insulating layer 3a, and a third insulating layer 3c on the second insulating layer 3b.

The insulating layer 3 includes circuit elements such as multiple thin-film transistors 31, 32, and 33, various signal lines, and capacitors, provided for each sub-pixel 21, 22, and 23. The first insulating layer 3a can have thin-film transistors 31, 32, and 33 arranged therein. The signal lines can include gate lines, data lines, power lines, and reference lines, and the thin-film transistors 31, 32, and 33 can include switching thin-film transistors, driving thin-film transistors, and sensing thin-film transistors. Each of the sub-pixels 21, 22, and 23 is defined by the intersection structure of the gate lines and data lines. The insulating layer 3 can surround the thin-film transistors 31, 32, and 33.

The switching thin-film transistor switches according to the gate signal supplied to the gate line to supply the data voltage from the data line to the driving thin-film transistor.

The driving thin-film transistor switches according to the data voltage supplied from the switching thin-film transistor, generating data current from the power supplied through the power line, which is then supplied to the first electrode 4.

The sensing thin-film transistor senses the threshold voltage variation of the driving thin-film transistor, which causes image quality degradation, and in response to the sensing control signal supplied from the gate line or a separate sensing line, it supplies the current from the driving thin-film transistor to the reference line.

The capacitor serves to maintain the data voltage supplied to the driving thin-film transistor for one frame and is connected to the gate terminal and source terminal of the driving thin-film transistor, respectively.

The first thin-film transistor 31, the second thin-film transistor 32, and the third thin-film transistor 33 are arranged in the first insulating layer 3a for each individual sub-pixel 21, 22, and 23. The first thin-film transistor 31 is connected to the first electrode 4 disposed on the first sub-pixel 21 and can apply a driving voltage to emit light of the color corresponding to the first sub-pixel 21. The first thin-film transistor 31, second thin-film transistor 32, and third thin-film transistor 33 can be located in the same thin-film transistor layer, but the embodiments in this disclosure are not limited to this.

The second thin-film transistor 32 is connected to the first electrode 4 disposed on the second sub-pixel 22 and can apply a driving voltage to emit light of the color corresponding to the second sub-pixel 22.

The third thin-film transistor 33 is connected to the first electrode 4 disposed on the third sub-pixel 23 and can apply a driving voltage to emit light of the color corresponding to the third sub-pixel 23.

The first sub-pixel 21, second sub-pixel 22, and third sub-pixel 23 each supply a predetermined current to the light-emitting layer according to the data voltage of the data line when a gate signal is input from the gate line, using their respective transistors 31, 32, and 33. As a result, the light-emitting layers of the first sub-pixel 21, second sub-pixel 22, and third sub-pixel 23 can emit light at a predetermined brightness according to the supplied current.

The insulating layer 3 can protect the transistors 31, 32, and 33. The insulating layer 3 can be made of an inorganic insulating material, but it is not limited to this, and can also be made of an organic insulating material. For example, the insulating layer 3 can be made of an inorganic material such as silicon nitride (SiNx), silicon oxide (Siox), or aluminum oxide (Al2O3), but the embodiments in this disclosure are not limited to these materials. The first insulating layer 3a, the second insulating layer 3b, and the third insulating layer 3c can be made of inorganic materials such as silicon nitride (SiNx), silicon oxide (Siox), or aluminum oxide (Al2O3), but the embodiments of this disclosure are not limited thereto.

A plurality of reflective electrode layers can be arranged on the insulating layer 3. The reflective electrode layers can include a first reflective electrode layer on the first insulating layer 3a, a second reflective electrode layer on the second insulating layer 3b, and a third reflective electrode layer on the third insulating layer 3c. The first reflective electrode layer can include a first reflective electrode 42a and a first connection electrode 42a′, the second reflective electrode layer can include a second reflective electrode 42b and a second connection electrode 42b′, and the third reflective electrode layer can include a third reflective electrode 42c and a third connection electrode 42c′. The first reflective electrode 42a and the first connection electrode 42a′ can be arranged in the same layer and can include the same material. The second reflective electrode 42b and the second connection electrode 42b′ can be arranged in the same layer and can include the same material. The third reflective electrode 42c and the third connection electrode 42c′ can be arranged in the same layer and can include the same material.

Each reflective electrode layer can include a reflective material to reflect light. For example, the reflective material can be metal, but it is not limited to this, and any other material capable of reflecting light can also be used. For example, the reflective material can include aluminum (Al) or silver (Ag), but the embodiments in this disclosure are not limited to these.

The reflective electrode 42 is disposed at a relatively lower position than the common light-emitting layer 5, allowing reflection of the light emitted from the common light-emitting layer 5 upwards. Here, the upward direction refers to the direction in which the user perceives the light, which may, for example, be the side where the encapsulation layer 8 or the color filter layer 9 is disposed. As a result, the first sub-pixel 21, second sub-pixel 22, and third sub-pixel 23 can achieve higher light efficiency compared to when the reflective electrode 42 is not present, and the user can perceive a high luminance, i.e., a sharper image, through the improved light efficiency.

The first reflective electrode 42a can be disposed on the first insulating layer 3a in the first emissive area EA1 and the first non-emissive area NEA1 of the first sub-pixel 21, the second reflective electrode 42b can be disposed on the first insulating layer 3a in the second emissive area EA2 and the second non-emissive area NEA2 of the second sub-pixel 22, and the third reflective electrode 42c can be disposed on the first insulating layer 3a in the third emissive area EA3 and the third non-emissive area NEA3 of the third sub-pixel 23. In each non-emissive area NEA1, NEA2, and NEA3, the first reflective electrode 42a and the first connection electrode 42a′ can be electrically connected to each transistor 31, 32, and 33.

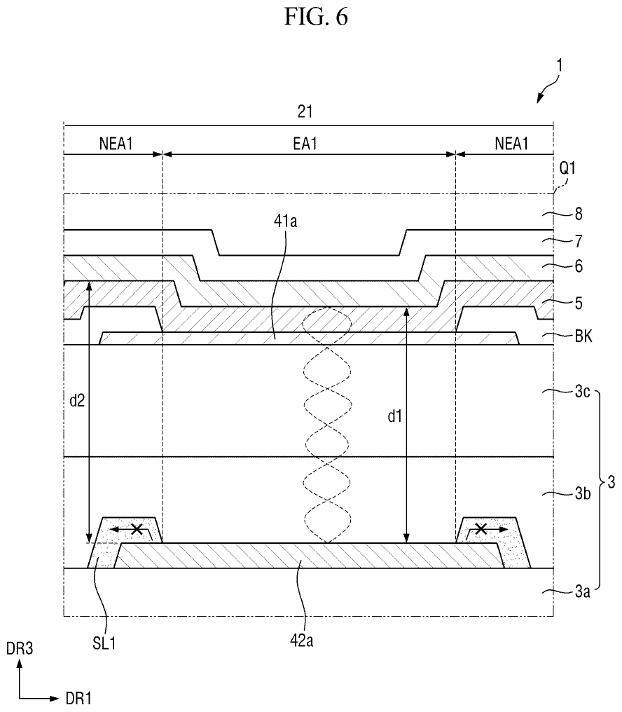

The first non-emissive area NEA1 of the first sub-pixel 21 can include a first auxiliary layer SL1 disposed on the first reflective electrode 42a. The first auxiliary layer SL1 can be directly disposed on the top and side surfaces of the first reflective electrode 42a. A description of the first auxiliary layer SL1, along with the second auxiliary layer SL2 and the third auxiliary layer SL3, will be provided in detail with reference to FIG. 2 and FIG. 6.

A second insulating layer 3b can be disposed on the first reflective electrode 42a, the first connection electrode 42a′, and the first auxiliary layer SL1. The second insulating layer 3b can reflect the step difference caused by the thickness of the first reflective electrode 42a, the first connection electrode 42a′, and the first auxiliary layer SL1.

On the second insulating layer 3b, the second reflective electrode 42b and the second connection electrode 42b′ can be disposed. The second reflective electrode 42b can be disposed in the second subpixel 22, and the second connection electrode 42b′ can be disposed in the first and third subpixels 21 and 23, respectively. The second reflective electrode 42b can be connected to the first connection electrode 42a′ in the second non-emissive area NEA2 of the second subpixel 22 through the first contact hole CT1. The second connection electrode 42b′ can be connected to the first reflective electrode 42a and the first connection electrode 42a′ in the non-emissive areas NEA1 and NEA3, respectively, through the first contact hole CT1.

The second non-emissive area NEA2 of the second subpixel 22 can include a second auxiliary layer SL2 disposed on the second reflective electrode 42b. The second auxiliary layer SL2 can be directly disposed on the top and side surfaces of the second reflective electrode 42b.

A third insulating layer 3c can be disposed on the second reflective electrode 42b, the second connection electrode 42b′, and the second auxiliary layer SL2. The third insulating layer 3c can reflect the step difference caused by the thickness of the second reflective electrode 42b, the second connection electrode 42b′, and the second auxiliary layer SL2.

On the third insulating layer 3c, the third reflective electrode 42c and the third connection electrode 42c′ can be disposed. The third reflective electrode 42c is disposed in the third sub-pixel 23, and the third connection electrode 42c′ can be disposed in the first and second sub-pixels 21 and 22, respectively. The third reflective electrode 42c can be connected to the second connection electrode 42b′ in the third non-emissive area NEA3 of the third sub-pixel 23 through the second contact hole CT2. The third connection electrode 42c′ can be connected to the second connection electrode 42b′ and the second reflective electrode 42b in the non-emissive areas NEA1 and NEA2, respectively, through the second contact hole CT2.

The third non-emissive area NEA3 of the third subpixel 23 can include a third auxiliary layer SL3 disposed on the third reflective electrode 42c. The third auxiliary layer SL3 can be directly disposed on the top and side surfaces of the third reflective electrode 42c.

A trench portion TRP can be formed in the insulating layer 3. For example, the trench portion TRP can be formed in the non-emissive areas NEA1, NEA2, and NEA3. As shown in FIG. 2 and FIG. 3, the trench portion TRP can be formed by penetrating parts of the third insulating layer 3c and the second insulating layer 3b, but the embodiments of this disclosure are not limited to this. In the display device 1 according to an embodiment, since a trench portion TRP is formed between adjacent sub-pixels 21, 22, 23, lateral leakage current LLC caused by the common light-emitting layer 5 between adjacent sub-pixels 21, 22, 23 can be improved.

As shown in FIG. 2, in the emission areas EA1, EA2, and EA3, the distance between the reflective electrodes 42a, 42b, and 42c and the cathode electrode 6 can differ from each other. For example, the distance between the first reflective electrode 42a and the cathode electrode 6 can be the largest, followed by the distance between the second reflective electrode 42b and the cathode electrode 6, with the distance between the third reflective electrode 42c and the cathode electrode 6 being the smallest.

In this way, the reflective electrodes 42a, 42b, and 42c are formed at various distances (or resonant distances) from the cathode electrode 6 because, depending on the spacing, the reflection and re-reflection between the reflective electrodes 42a, 42b, 42c and the cathode electrode 6 can enhance the light extraction efficiency of different colors of light. Therefore, in the first sub-pixel 21, the light extraction efficiency for red light can be enhanced, in the second sub-pixel 22, the light extraction efficiency for green light can be enhanced, and in the third sub-pixel 23, the light extraction efficiency for blue light can be enhanced.

The anode electrode 41 can include the first anode electrode 41a of the first sub-pixel 21, the second anode electrode 41b of the second sub-pixel 22, and the third anode electrode 41c of the third sub-pixel 23. The anode electrodes 41a, 41b, and 41c can be disposed on the anode electrode layer, placed in the same layer, and include the same material.

In the third emissive area EA3 of the third sub-pixel 23, the third anode electrode 41c can be directly disposed on the third reflective electrode 42c. In each of the non-emissive area NEA1, NEA2, and NEA3 of the first to third sub-pixels 21 to 23, the anode electrodes 41a, 41b, and 41c can be directly disposed on the third connection electrode 42c′ and the third reflective electrode 42c.

Each of the anode electrodes 41a, 41b, and 41c can be electrically connected with the thin-film transistors 31, 32, and 33 in each non-emissive area NEA1, NEA2, and NEA3.

The anode electrodes 41a, 41b, and 41c can include materials with high light transmittance. For example, the anode electrodes 41a, 41b, and 41c can include ITO, IZO, or TiN, but are not limited thereto.

A bank BK can be disposed on the anode electrodes 41a, 41b, and 41c. The bank BK can be made of inorganic materials such as silicon nitride (SiNx), silicon oxide (Siox), or aluminum oxide (Al2O3), but the embodiments in this disclosure are not limited to these materials. The bank BK can be disposed on the non-emissive areas NEA1, NEA2, and NEA3.

In the emissive areas EA1, EA2, and EA3, the bank BK can expose the top surfaces of the anode electrodes 41a, 41b, and 41c, defining the emissive areas EA1, EA2, and EA3. As shown in FIG. 2, the bank BK can be in contact with the upper surface and the side surface of the anode electrodes 41a, 41b, and 41c. As shown in FIG. 3, in the non-emissive areas NEA1, NEA2, NEA3, the bank BK can cover the entire upper surface of the anode electrodes 41a, 41b, and 41c, but the embodiments of the present disclosure are not limited thereto.

The common light-emitting layer 5 is formed on the anode electrodes 41a, 41b, 41c and the bank BK. The common light-emitting layer 5 can contact the upper surface of the anode electrodes 41a, 41b, 41c. The common light-emitting layer 5 can directly contact the upper surface of the anode electrodes 41a, 41b, 41c, the upper and side surfaces of the bank BK, and the upper surface of the insulating layer 3. The common light-emitting layer 5 can also extend into the trench part TRP.

According to one embodiment, the organic light-emitting device OLED can include the first electrode 4, ANO, the cathode electrode 6, CAT, and the common light-emitting layer 5 between the first electrode 4 and the cathode electrode 6.

The common light-emitting layer 5 can be configured to emit white (W) light. To achieve this, the common light-emitting layer 5 can include a plurality of stacks that emit light of different colors. Specifically, the common light-emitting layer 5 can include a first stack, a second stack, and a charge generation layer CGL disposed between the first stack and the second stack.

The cathode electrode 6 is formed on the common light-emitting layer 5. The cathode electrode 6 can function as the cathode of the display device 1. The cathode electrode 6 is formed in each of the sub-pixels 21, 22, and 23 and between the sub-pixels 21, 22, and 23, similar to the common light-emitting layer 5.

In an embodiment, the display device 1 can have a cathode electrode 6 made of a semi-transparent electrode to implement white light with high light efficiency in the top emission configuration. As a result, micro cavity effects can be obtained for each of the first to third sub-pixels 21, 22, and 23. The micro cavity effect can be achieved by repeated reflection and re-reflection of light between the cathode electrode 6 and the reflective electrode 42, which improves light extraction efficiency.

Meanwhile, since the cathode electrode 6 is formed on the upper surface of the common light-emitting layer 5, it can be shaped according to the profile of the common light-emitting layer 5. Since the common light-emitting layer 5 is formed following the profile of the first electrode 4 in the light-emitting region, the cathode electrode 6 can ultimately be formed to follow the profile of the first electrode 4. Additionally, the capping layer 7 on the cathode electrode 6 can also be formed to follow the profile of the cathode electrode 6.

The capping layer 7 can be made of an inorganic insulating material, but is not limited thereto. The capping layer 7 can be disposed on the cathode electrode 6 to protect the organic light-emitting device (OLED).

The encapsulation layer 8 is formed on the cathode electrode 6 to prevent or reduce external moisture from penetrating into the common light-emitting layer 5. This encapsulation layer 8 can be made of an inorganic insulating material or can be formed in an alternating stack structure of inorganic and organic insulating materials, but is not limited to these configurations.

The color filter layer 9 is formed on the encapsulation layer 8. The color filter layer 9 can include a first color filter 91 of red (R) provided in the first sub-pixel 21, a second color filter 92 of green (G) provided in the second sub-pixel 22, and a third color filter 93 of blue (B) provided in the third sub-pixel 23, but is not limited to these configurations.

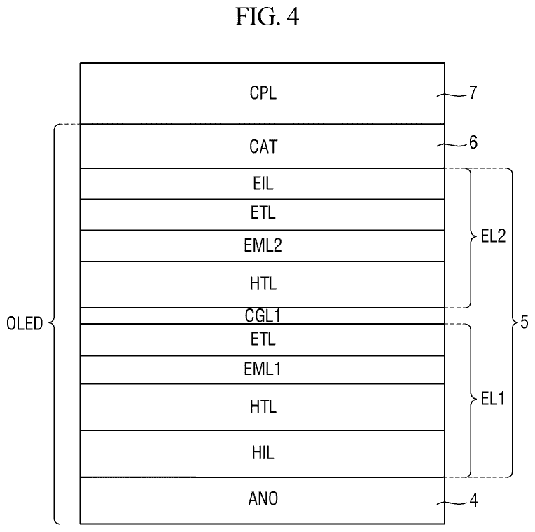

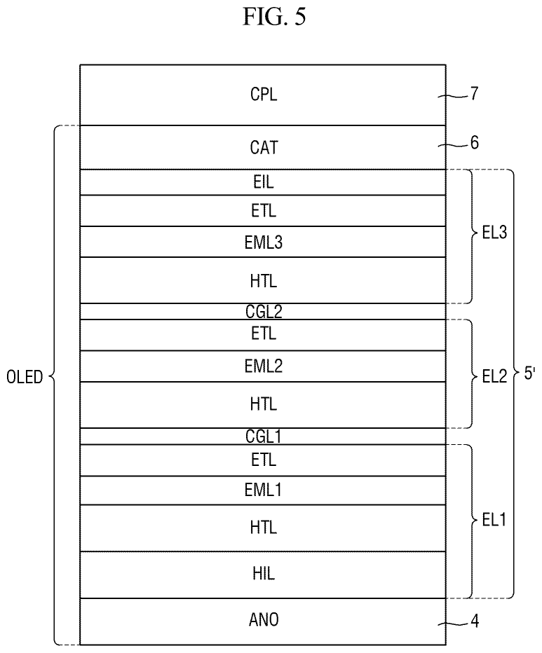

FIG. 4 is a cross-sectional view of the organic light-emitting element according to FIG. 2. FIG. 5 is a cross-sectional view of an alternative of the organic light-emitting element according to FIG. 2.

Referring to FIGS. 1 to 4, the common light-emitting layer 5 can be formed to include the first stack EL1, second stack EL2, and first charge generation layer CGL1 provided on the first electrode 4.

The first stack EL1 is provided on the first electrode 4 and can have a structure where a hole injecting layer HIL, a hole transporting layer HTL, a blue (B) emitting layer EML1, and an electron transporting layer ETL are sequentially stacked.

The first stack EL1 can be disposed between the first sub-pixel 21 and the second sub-pixel 22, as well as between the second sub-pixel 22 and the third sub-pixel 23.

The first charge generation layer CGL1 serves to supply charges to the first stack EL1 and the second stack EL2. The first charge generation layer CGL1 can include an N-type charge generation layer that supplies electrons to the first stack EL1 and a P-type charge generation layer that supplies holes to the second stack EL2. The N-type charge generation layer can be made by doping a metal material.

The second stack EL2 is provided on the first stack EL1 and can have a structure where a hole transporting layer HTL, a yellow-green (YG) emitting layer EML2, an electron transporting layer ETL, and an electron injecting layer EIL are sequentially stacked.

The second stack EL2 can be disposed between the first sub-pixel 21 and the second sub-pixel 22, as well as between the second sub-pixel 22 and the third sub-pixel 23.

As a result, the common light-emitting layer 5 can be provided as a common layer across the entire first to third sub-pixels 21, 22, and 23, as shown in FIGS. 2 and 3.

Referring to FIG. 5, the common light-emitting layer 5′ of the organic light-emitting device (OLED) according to an embodiment can include the first stack EL1, the second stack EL2, the third stack EL3, the first charge generation layer CGL1 between the first stack EL1 and the second stack EL2, and the second charge generation layer CGL2 between the second stack EL2 and the third stack EL3, provided on the first electrode 4.

The first stack EL1 is provided on the first electrode 4 and can have a structure where a hole injecting layer HIL, a hole transporting layer HTL, a blue (B) emitting layer EML1, and an electron transporting layer ETL are sequentially stacked.

The first stack EL1 can be disposed between the first sub-pixel 21 and the second sub-pixel 22, as well as between the second sub-pixel 22 and the third sub-pixel 23, For example, on the bank BK.

The first charge generation layer CGL1 serves to supply charges to the first stack EL1 and the second stack EL2. The first charge generation layer CGL1 can include an N-type charge generation layer that supplies electrons to the first stack EL1 and a P-type charge generation layer that supplies holes to the second stack EL2. The N-type charge generation layer can be made by doping a metal material.

The second stack EL2 is provided on the first stack EL1 and can have a structure where a hole transporting layer HTL, a green (G) emitting layer EML2, and an electron transporting layer ETL are sequentially stacked.

The second stack EL2 can be disposed between the first sub-pixel 21 and the second sub-pixel 22, as well as between the second sub-pixel 22 and the third sub-pixel 23, i.e., on the bank BK.

The second charge generation layer CGL2 serves to supply charge to the second stack EL2 and the third stack EL3. The second charge generation layer CGL2 can include an N-type charge generation layer to supply electrons to the second stack EL2 and a P-type charge generation layer to supply holes to the third stack EL3. The N-type charge generation layer can be made by doping a metal material.

The third stack EL3 is provided on the second stack EL2 and can have a structure where a hole transporting layer HTL, a red (R) emitting layer EML3, an electron transporting layer ETL, and an electron injecting layer EIL are sequentially stacked.

Referring to FIGS. 1 to 5, the charge generation layer CGL1, CGL2 can be disposed between the first sub-pixel 21 and the second sub-pixel 22, and between the second sub-pixel 22 and the third sub-pixel 23. Meanwhile, in the display device 1 according to an embodiment, since the common light-emitting layer 5 is disposed between each of the sub-pixels 21, 22, and 23, lateral leakage current can occur through the charge generation layers CGL1 and CGL2 to adjacent sub-pixels 21, 22, and 23 when any one of the sub-pixels emits light; however, a trench portion TRP can be formed between the sub-pixels 21, 22, and 23. The formation length of the common light-emitting layer 5 at the boundary of the sub-pixels 21, 22, and 23 can increase through the trench portion TRP, thereby lengthening the current path. As a result, side leakage current can be prevented or reduced. Furthermore, by separating the common light-emitting layer 5 in the trench portion TRP, side leakage current can be prevented in advance.

Referring again to FIGS. 2 and 3, the cathode electrode 6 is formed on the common light-emitting layer 5, the encapsulation layer 8 is formed on the cathode electrode 6, and the color filter layer 9 is formed on the encapsulation layer 8.

A black matrix can be provided between the first to third color filters 91, 92, and 93 to prevent or reduce color mixing between sub-pixels.

FIG. 6 is an enlarged cross-sectional view of Q1 area in FIG. 2.

Referring to FIGS. 2 and 6, according to an embodiment of the present disclosure, the display device 1 can have auxiliary layers SL1, SL2, and SL3 disposed on the reflective electrodes 42a, 42b, and 42c of the respective sub-pixels 21, 22, and 23. FIG. 6 illustrates a cross-section of the first sub-pixel 21, and since the function and arrangement of the first auxiliary layer SL1 of the first sub-pixel 21 can be identical or similar to the function and arrangement of the second and third auxiliary layers SL2 and SL3, the explanation will focus on the first sub-pixel 21.

The first reflective electrode 42a can be disposed in a portion of the first emissive area EA1 and the first non-emissive area NEA1.

The first auxiliary layer SL1 can be disposed in the first non-emissive area NEA1. However, the first auxiliary layer SL1 can be arranged so as not to overlap the first thin-film transistor 31.

The first auxiliary layer SL1 may not overlap with the first light-emitting region EA1, but the embodiments of this disclosure are not limited thereto.

The first auxiliary layer SL1 can include a metal. For example, the first auxiliary layer SL1 can include a material having a lower reflectance to light than the first reflective electrode 42a. For example, the first auxiliary layer SL1 can include a material having a higher absorbance to light than that of the first reflective electrode 42a. The term “light” in this specification can refer to light (or white light) emitted from the common light-emitting layer 5 of the respective sub-pixels 21, 22, and 23.

In the first emissive area EA1, the first reflective electrode 42a and the cathode electrode 6 can be spaced apart with a first separation distance d1. In contrast, in the first non-emissive area NEA1, the first reflective electrode 42a and the cathode electrode 6 can be spaced apart with a second separation distance d2. The second separation distance d2 can differ from the first separation distance d1. For example, the second separation distance d2 can be greater than the first separation distance d1, and the second separation distance d2 can be greater than the first separation distance d1 by the sum of the thickness of the first auxiliary layer SL1 and the thickness of the bank BK, though embodiments of this disclosure are not limited thereto. As described above with reference to FIGS. 2 and 3, the insulating layer 3 can reflect the step difference caused by the thicknesses of components disposed beneath the insulating layer 3, and the common light-emitting layer 5 can also reflect the step difference caused by the thicknesses of components disposed beneath the common light-emitting layer, though embodiments of this disclosure are not limited thereto.

The first separation distance d1 between the cathode electrode 6 and the first reflective electrode 42a can be designed to adjust the microcavity characteristics in the first sub-pixel 21.

However, according to an embodiment, in the first non-emissive area NEA1, light emitted from the common light-emitting layer 5 can be incident downward, reflected by the first reflective electrode 42a, with some of the light reflected from the first reflective electrode 42a capable of passing through the bank BK. In the first non-emissive area NEA1, when some of the light reflected from the first reflective electrode 42a passes through the bank BK, the separation distance d2 between the first reflective electrode 42a and the cathode electrode 6 becomes different from the first separation distance d1. As a result, the microcavity characteristics designed for the first sub-pixel 21 may not be maintained, causing a deviation between the color of light passing through the cathode electrode 6 in the first non-emissive area NEA1 and the color of light passing through the cathode electrode 6 in the first emissive area EA1.

However, according to an embodiment, the display device 1 can have the first auxiliary layer SL1 including a metal with a lower reflectance to light and a lower absorbance compared to the first reflective electrode 42a.

Consequently, illustrated in FIG. 6, light emitted downward from the common light-emitting layer 5 and reflected by the first reflective electrode 42a in the first non-emissive area NEAL can be absorbed by the first auxiliary layer SL1. Thus, the deviation between the color of light passing through the cathode electrode 6 in the first non-emissive area NEAL and the color of light passing through the cathode electrode 6 in the first emissive area EA1 can be improved.

For example, the first auxiliary layer SL1 can include titanium. For example, the first auxiliary layer SL1 can include TiN or MoTi, though embodiments of this disclosure are not limited thereto. For example, when the first auxiliary layer SL1 includes TiN, it can be thicker than the first anode electrode 41a, though embodiments of this disclosure are not limited thereto.

Hereinafter, descriptions of display devices according to other embodiments will be provided. In explaining the following embodiments, detailed descriptions of configurations that are the same as or similar to those described with reference to FIGS. 1 to 6 will be omitted to avoid redundancy.

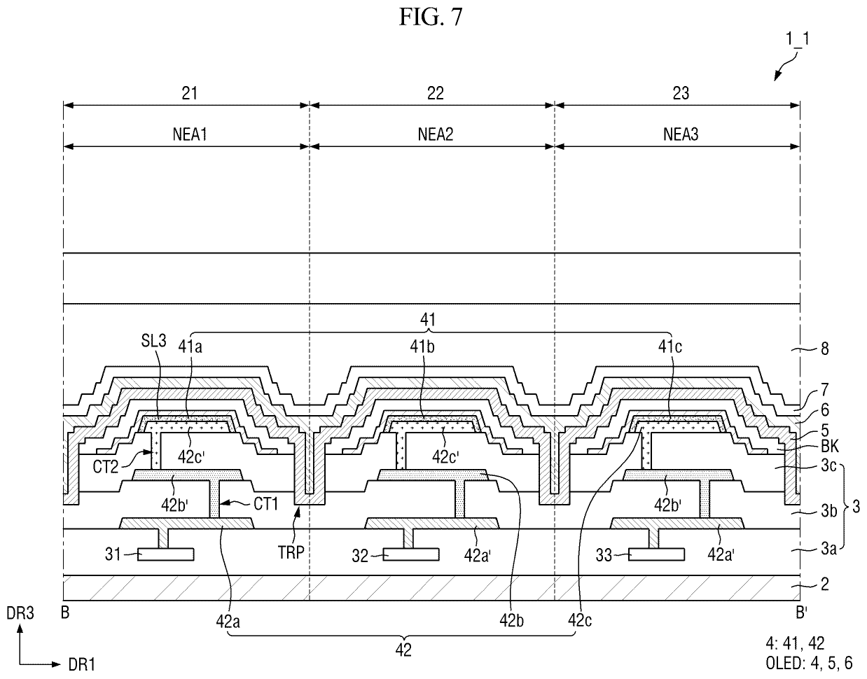

FIG. 7 is a cross-sectional view of a display device according to another embodiment of the present disclosure.

Referring to FIG. 7, a display device 1_1 according to this embodiment differs from the display device 1 according to FIG. 3 in that the third auxiliary layer SL3 can overlap the transistors 31, 32, and 33 of the respective sub-pixels 21, 22, and 23 in the non-emissive areas NEA1, NEA2, and NEA3.

More specifically, the third auxiliary layer SL3 can include a metal with a lower reflectance to light and a higher absorbance compared to the reflective electrodes 42a, 42b, and 42c. The third auxiliary layer SL3 can be disposed on the third connection electrode 42c′ or the third reflective electrode 42c and can cover the third connection electrode 42c′ or the third reflective electrode 42c. The third auxiliary layer SL3 can completely cover the third connection electrode 42c′ or the third reflective electrode 42c.

According to this embodiment, since the third auxiliary layer SL3 includes a metal with a lower reflectance to light and a higher absorbance compared to the reflective electrodes 42a, 42b, and 42c, the visibility of the first and second contact holes CT1 and CT2 in the non-emissive areas NEA1, NEA2, and NEA3 can be improved.

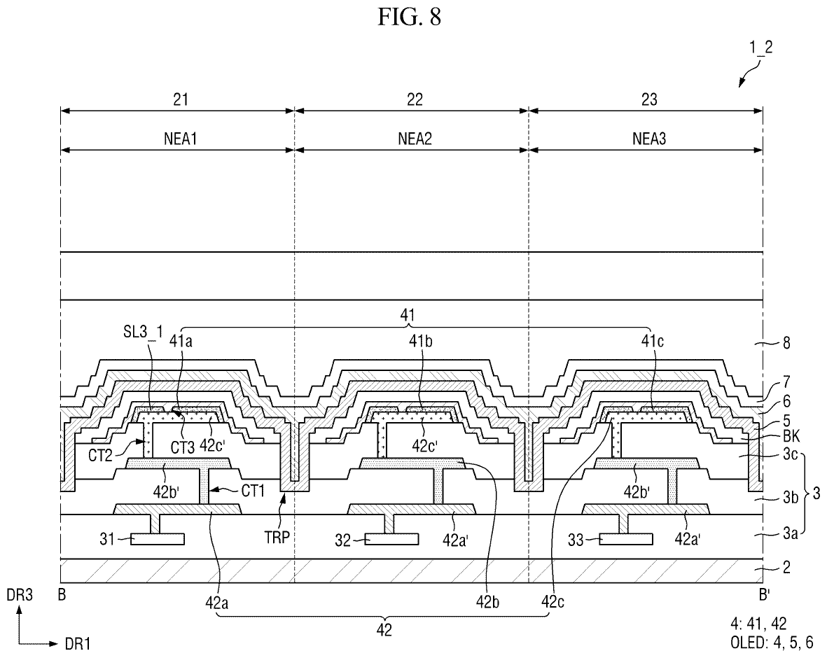

FIG. 8 is a cross-sectional view of a display device according to another embodiment of the present disclosure.

Referring to FIG. 2 and FIG. 8, a display device 1_2 according to this embodiment differs from the display device according to FIG. 2, FIG. 6, and FIG. 7 in that the auxiliary layer includes a black matrix material.

More specifically, the auxiliary layer according to this embodiment, as illustrated in FIG. 8 as SL3_1, can include a light-absorbing material containing a black matrix material. For example, the auxiliary layer can include an organic insulating material or an inorganic insulating material.

Referring to FIG. 6 as well, in this embodiment, in the first emissive area EA1, the first reflective electrode 42a and the cathode electrode 6 can be spaced apart with a first separation distance d1. In contrast, in the first non-emissive area NEA1, the first reflective electrode 42a and the cathode electrode 6 can be spaced apart with a second separation distance d2. The second separation distance d2 can differ from the first separation distance d1. For example, the second separation distance d2 can be greater than the first separation distance d1, and the second separation distance d2 can be greater than the first separation distance d1 by the sum of the thickness of the first auxiliary layer SL1 and the thickness of the bank BK, though embodiments of this disclosure are not limited thereto. As described above with reference to FIGS. 2 and 3, the insulating layer 3 can reflect the step difference caused by the thicknesses of components disposed beneath the insulating layer 3, and the common light-emitting layer 5 can also reflect the step difference caused by the thicknesses of components disposed beneath the common light-emitting layer, though embodiments of this disclosure are not limited thereto.

The first separation distance d1 between the cathode electrode 6 and the first reflective electrode 42a can be designed to adjust the microcavity characteristics in the first sub-pixel 21.

However, according to this embodiment, in the display device 1_2, even in the first non-emissive area NEA1, light emitted from the common light-emitting layer 5 can be incident downward and reflected by the first reflective electrode 42a, with some of the light reflected from the first reflective electrode 42a capable of passing through the bank BK. In the first non-emissive area NEA1, when some of the light reflected from the first reflective electrode 42a passes through the bank BK, the separation distance d2 between the first reflective electrode 42a and the cathode electrode 6 becomes different from the first separation distance d1. As a result, the microcavity characteristics designed for the first sub-pixel 21 may not be maintained, causing a deviation between the color of light passing through the cathode electrode 6 in the first non-emissive area NEA1 and the color of light passing through the cathode electrode 6 in the first emissive area EA1.

However, according to this embodiment, the display device 1_2 can include a first auxiliary layer that contains a black matrix material.

As a result, light emitted downward from the common light-emitting layer 5 and reflected by the first reflective electrode 42a in the first non-emissive area NEA1 can be absorbed by the first auxiliary layer. Thus, the deviation between the color of light passing through the cathode electrode 6 in the first non-emissive area NEA1 and the color of light passing through the cathode electrode 6 in the first emissive area EA1 can be improved.

According to this embodiment, in the display device 1_2, the third auxiliary layer in the non-emissive areas NEA1, NEA2, and NEA3 of each sub-pixel 21, 22, and 23 may not be disposed on the transistors 31, 32, and 33. However, as illustrated in FIG. 8, the third auxiliary layer SL3_1 can overlap the transistors 31, 32, and 33 in the non-emissive areas NEA1, NEA2, and NEA3, partially covering the third connection electrode 42c′ or the third reflective electrode 42c, and exposing a portion of the upper surface of the third connection electrode 42c′ or the third reflective electrode 42c. For example, on the third connection electrode 42c′ or the third reflective electrode 42c, the third auxiliary layer SL3_1 can include a third contact hole CT3. Through the third contact hole CT3, the anode electrodes 42a, 42b, and 42c can be connected to the third connection electrode 42c′ or the third reflective electrode 42c. The reflectance to light of the third auxiliary layer SL3_1 can be lower than the reflectance to light of the third reflective electrode 42c.

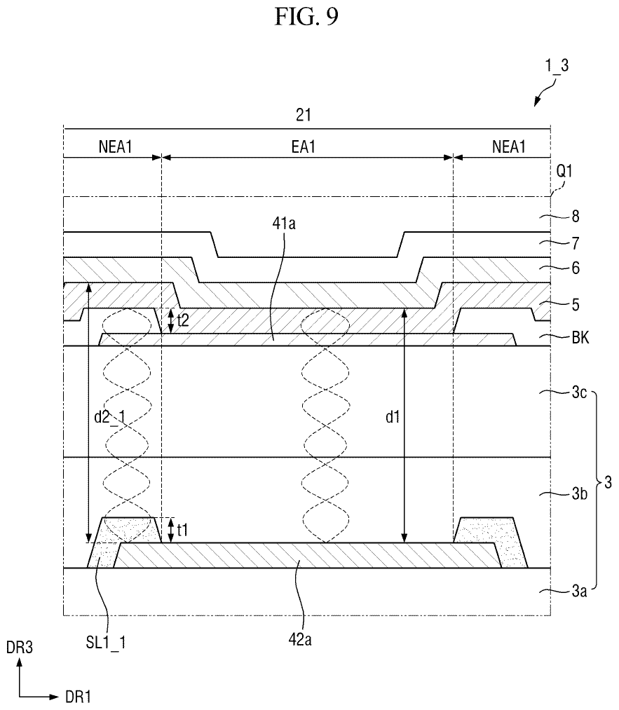

FIG. 9 is a cross-sectional view of a display device according to another embodiment of the present disclosure.

Referring to FIG. 9, a display device 1_3 according to this embodiment differs from the display device 1 according to FIG. 6 in that the auxiliary layer has a first thickness t1. FIG. 9 illustrates the first sub-pixel 21. The function and characteristics of the first auxiliary layer SL1_1 of the first sub-pixel 21 can be applied identically or similarly to the second and third auxiliary layers of the second and third sub-pixels 22 and 23.

More specifically, the first auxiliary layer SL1_1 can serve a thickness compensation function. The first auxiliary layer SL1_1 can include the same material as the bank BK, though embodiments of this disclosure are not limited thereto. For example, the first auxiliary layer SL1_1 can be made of inorganic materials such as silicon nitride (SiNx), silicon oxide (Siox), or aluminum oxide (Al2O3), though embodiments of this disclosure are not limited thereto.

As described above with reference to FIG. 6, in the first emissive area EA1, the first reflective electrode 42a and the cathode electrode 6 can be spaced apart with a first separation distance d1. In contrast, in the first non-emissive area NEA1, the first reflective electrode 42a and the cathode electrode 6 can be spaced apart with a second separation distance d2_1. The second separation distance d2_1 can differ from the first separation distance d1. For example, the second separation distance d2_1 can be greater than the first separation distance d1, and the second separation distance d2_1 can be greater than the first separation distance d1 by the sum of the thickness t1 of the first auxiliary layer SL1_1 and the thickness t2 of the bank BK, though embodiments of this disclosure are not limited thereto. The insulating layer 3 can reflect the step difference caused by the thicknesses of components disposed beneath the insulating layer 3, and the common light-emitting layer 5 can also reflect the step difference caused by the thicknesses of components disposed beneath the common light-emitting layer 5, though embodiments of this disclosure are not limited thereto.

The first separation distance d1 between the cathode electrode 6 and the first reflective electrode 42a can be designed to adjust the microcavity characteristics in the first sub-pixel 21.

However, according to this embodiment, in the display device 1_3, even in the first non-emissive area NEA1, light emitted from the common light-emitting layer 5 can be incident downward and reflected by the first reflective electrode 42a, with some of the light reflected from the first reflective electrode 42a capable of passing through the first auxiliary layer SL1_1 and the bank BK. In the first non-emissive area NEA1, when some of the light reflected from the first reflective electrode 42a passes through the first auxiliary layer SL1_1 and the bank BK, the separation distance d2_1 between the first reflective electrode 42a and the cathode electrode 6 becomes different from the first separation distance d1. As a result, the microcavity characteristics designed for the first sub-pixel 21 may not be maintained, causing a deviation between the color of light passing through the cathode electrode 6 in the first non-emissive area NEA1 and the color of light passing through the cathode electrode 6 in the first emissive area EA1.

However, according to this embodiment, in the display device 1_3, the thickness t1 of the first auxiliary layer SL1_1 and the thickness t2 of the bank BK can be designed to match the microcavity characteristics of the first emissive area EA1 of the first sub-pixel 21.

The thickness t1 of the first auxiliary layer SL1_1 and the thickness t2 of the bank BK can be designed based on Equation 1 below.

$$( t 1 + t 2 ) = \frac{λ}{2} \times ( 2 m ) \qquad [ Equation 1 ]$$

Here, t1 is the thickness of the auxiliary layer, t2 is the thickness of the bank BK, λ is the target wavelength in each sub-pixel 21, 22, and 23, and m is an integer.

In this specification, the target wavelength in each sub-pixel 21, 22, and 23 can differ for each sub-pixel 21, 22, and 23. For example, the target wavelength of the first sub-pixel 21 can be in the red wavelength range, the target wavelength of the second sub-pixel 22 can be in the green wavelength range, and the target wavelength of the third sub-pixel 23 can be in the blue wavelength range.

According to this embodiment, in the display device 1_3, since the microcavity characteristics of the light passing through the cathode electrode 6 in the first non-emissive area NEA1 and the light passing through the cathode electrode 6 in the first emissive area EA1 are matched, color deviation can be eliminated.

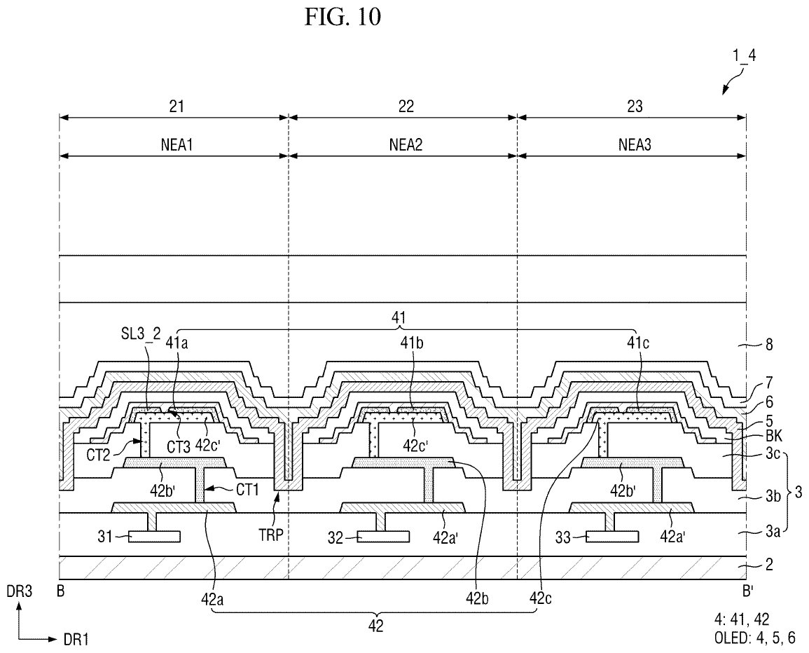

FIG. 10 is a cross-sectional view of a display device according to another embodiment of the present disclosure.

Referring to FIGS. 2 and 10, a display device 1_4 according to this embodiment can have an auxiliary layer that, as in FIG. 9, can serve a thickness compensation function, and while the third auxiliary layer in the non-emissive areas NEA1, NEA2, and NEA3 of each sub-pixel 21, 22, and 23 may not be disposed on the transistors 31, 32, and 33, the third auxiliary layer SL3_2 overlaps the transistors 31, 32, and 33 of each sub-pixel 21, 22, and 23 in the non-emissive areas NEA1, NEA2, and NEA3, partially covering the third connection electrode 42c′ or the third reflective electrode 42c and exposing a portion of the upper surface of the third connection electrode 42c′ or the third reflective electrode 42c. For example, on the third connection electrode 42c′ or the third reflective electrode 42c, the third auxiliary layer SL3_1 can include a third contact hole CT3. Through the third contact hole CT3, the anode electrodes 42a, 42b, and 42c can be connected to the third connection electrode 42c′ or the third reflective electrode 42c.

Further details are as described above with reference to FIG. 9 and will be omitted here.

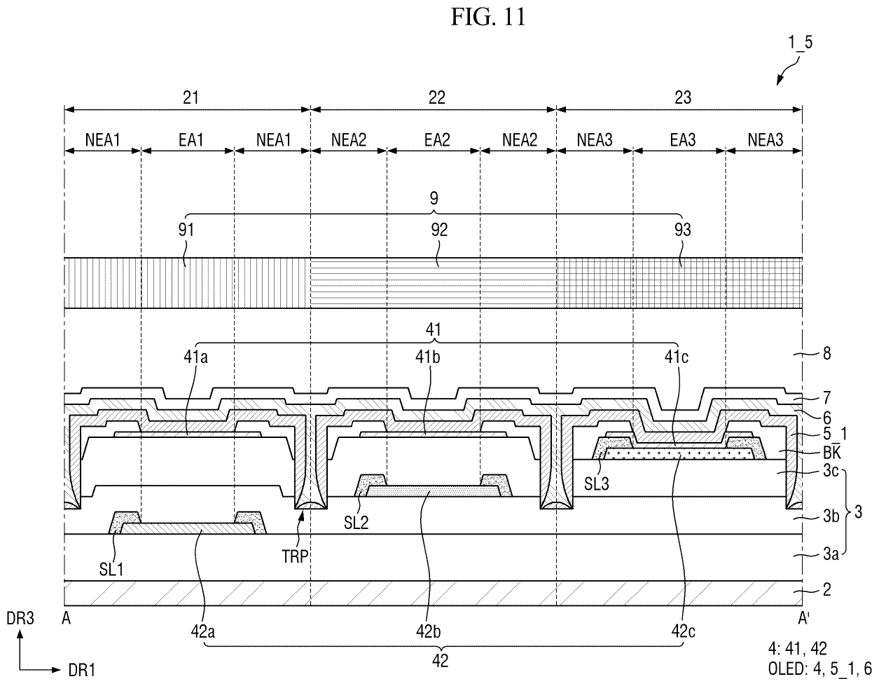

FIG. 11 is a cross-sectional view of a display device according to another embodiment of the present disclosure.

Referring to FIG. 11, a display device 1_5 according to the embodiment of FIG. 11 differs from the display device 1 according to the embodiment of FIG. 2 in that the common light-emitting layer 5_1 is included.

More specifically, the common light-emitting layer 5_1 can be physically separated at the boundaries between adjacent sub-pixels 21, 22, and 23.

For example, the common light-emitting layer 5_1 can be physically separated in the non-emission areas NEA1, NEA2, and NEA3. The common light-emitting layer 5_1 can be physically separated in the non-emission areas NEA1, NEA2, and NEA3 by a trench portion TRP.

For example, the common light-emitting layer 5_1 can be divided into portions that are placed on the side surfaces of the insulating layers 3 in the non-emission areas NEA1, NEA2, and NEA3 and on the side surfaces of the bank BK, as well as portions placed on the upper surface of the insulating layer 3 in the trench portion TRP formed in the non-emission areas NEA1, NEA2, and NEA3. The portion disposed on the side surface of the insulating layer 3 and the side surface of the bank BK in the non-emissive areas NEA1, NEA2, and NEA3, and the portion disposed on the upper surface of the insulating layer 3 where the trench portion TRP is formed, can be physically separated.

According to this embodiment, in the display device 1_1, the common light-emitting layer 5_1 can be physically separated between adjacent sub-pixels 21, 22, and 23, and the common light-emitting layer 5_1 can be physically separated at the same or substantially same level in each non-emissive area NEA1, NEA2, and NEA3. As a result, lateral leakage current LLC caused by the common light-emitting layer 5_1 can be improved.

Further details are as described above with reference to FIG. 2 and will be omitted here.

The display device according to various embodiments of this disclosure can be described as follows.

A display device according to various embodiments of this disclosure includes a substrate including an emissive area and a non-emissive area surrounding the emissive area, a reflective electrode on the substrate, an auxiliary layer on the reflective electrode, and an organic light-emitting element on the reflective electrode and the auxiliary layer, wherein the auxiliary layer is disposed in the non-emissive area.

In the display device according to various embodiments of this disclosure, the reflective electrode can be disposed in the emissive area and a portion of the non-emissive area.

In the display device according to various embodiments of this disclosure, the auxiliary layer can directly contact an upper surface and a side surface of the reflective electrode in the non-emissive area.

In the display device according to various embodiments of this disclosure, the organic light-emitting element can include an anode electrode on the reflective electrode and the auxiliary layer, a common light-emitting layer on the anode electrode, and a cathode electrode on the common light-emitting layer.

The display device according to various embodiments of this disclosure can further include a bank disposed between the anode electrode and the common light-emitting layer, wherein the bank can be disposed in the non-emissive area.

In the display device according to various embodiments of this disclosure, the second separation distance between the reflective electrode and the cathode electrode in the non-emissive area can be greater than the first separation distance between the reflective electrode and the cathode electrode in the emissive area.

In the display device according to various embodiments of this disclosure, the auxiliary layer can include a metal, and the reflectance of the auxiliary layer to light can be lower than the reflectance of the reflective electrode to light.

In the display device according to various embodiments of this disclosure, the absorbance of the auxiliary layer to light can be greater than the absorbance of the reflective electrode to light.

In the display device according to various embodiments of this disclosure, the auxiliary layer can include a light-shielding material.

In the display device according to various embodiments of this disclosure, a transmittance of the auxiliary layer to light maybe greater than the transmittance of the reflective electrode to light.

In the display device according to various embodiments of this disclosure, a thickness t1 of the auxiliary layer and a thickness t2 of the bank satisfy the following equation: (t1+t2)=λ/2×(2 m) where t1 is the thickness of the auxiliary layer, t2 is the thickness of the bank, λ is a target wavelength of the emissive area, and m is an integer.

In the display device according to various embodiments of this disclosure, the reflective electrode is disposed in the emissive area and the non-emissive area, the display device can further include a transistor between the substrate and the reflective electrode in the non-emissive area, and the reflective electrode is connected to the transistor in the non-emissive area.

In the display device according to various embodiments of this disclosure, the auxiliary layer can overlap the transistor.

In the display device according to various embodiments of this disclosure, the auxiliary layer can partially expose an upper surface of the reflective electrode, and the anode electrode can connect to the exposed upper surface of the reflective electrode.

The embodiments advantageously allow the reflective electrode to extend into the non-emissive area. In the embodiments, some of the light emitted from the common light-emitting layer can pass through the bank, despite the bank being disposed in the non-emissive area. Since the insulating layer reflects the step difference of the reflective electrode and/or the bank, the separation distance between the cathode electrode and the reflective electrode in the non-emissive area can differ from that in the emissive area. The embodiments advantageously block light reflected by the reflective electrode in the non-emissive area by disposing an auxiliary layer on top of the reflective electrode. This mitigates the occurrence of color deviation in the non-emissive area.

The embodiments advantageously provide an auxiliary layer on top of the reflective electrode in the non-emissive area, with its thickness adjustable based on the separation distance between the cathode electrode and the reflective electrode in the emissive area and the constructive interference condition. This mitigates the occurrence of color deviation in the non-emissive area.

The embodiments are advantageous for providing a display device with high color reproducibility by improving the occurrence of color deviation in the non-emissive area.

However, the effects achievable through this disclosure are not limited to the aforementioned, and additional effects not explicitly described herein can be readily understood by those skilled in the art based on the disclosure.

Although the embodiments have been described with reference to the attached drawings, it will be understood by those skilled in the art that the described technical configurations can be implemented in other specific forms without altering the technical essence or essential features. Therefore, it should be understood that the embodiments described above are exemplary and not limited in all respects. Moreover, the scope of the embodiments is determined by the claims that follow, rather than by the detailed description. Any modifications or variations derived from the meaning, scope, and equivalent concepts of the patent claims are to be considered as falling within the scope of the embodiments.

### DESCRIPTION OF REFERENCE NUMERALS

1: display device
2: substrate
3: insulating layer
4: first electrode
5: common light-emitting layer
6: cathode electrode
7: capping layer
8: encapsulation layer
9: color filter layer
BK: bank

What is claimed is:

1. A display device comprising:
a substrate including an emissive area and a non-emissive area;
a reflective electrode on the substrate;
an auxiliary layer on the reflective electrode; and
an organic light-emitting element on the reflective electrode and the auxiliary layer,
wherein the auxiliary layer is disposed in the non-emissive area.

2. The display device of claim 1, wherein the reflective electrode is disposed in the emissive area and a portion of the non-emissive area.

3. The display device of claim 2, wherein the auxiliary layer directly contacts an upper surface and a side surface of the reflective electrode in the non-emissive area.

4. The display device of claim 2, wherein the organic light-emitting element includes:
an anode electrode on the reflective electrode and the auxiliary layer,
a common light-emitting layer on the anode electrode, and
a cathode electrode on the common light-emitting layer.

5. The display device of claim 4, further comprising a bank disposed between the anode electrode and the common light-emitting layer,
wherein the bank is disposed in the non-emissive area.

6. The display device of claim 5, wherein a second separation distance between the reflective electrode and the cathode electrode in the non-emissive area is greater than a first separation distance between the reflective electrode and the cathode electrode in the emissive area.

7. The display device of claim 6, wherein the auxiliary layer includes a metal, and
wherein a reflectance of the auxiliary layer to light is lower than a reflectance of the reflective electrode to light.

8. The display device of claim 7, wherein an absorbance of the auxiliary layer to light is greater than an absorbance of the reflective electrode to light.

9. The display device of claim 6, wherein the auxiliary layer includes a light-shielding material.

10. The display device of claim 6, wherein a transmittance of the auxiliary layer to light is greater than a transmittance of the reflective electrode to light.

11. The display device of claim 10, wherein a thickness t1 of the auxiliary layer and a thickness t2 of the bank satisfy a following equation:
$$( t 1 + t 2 ) = λ / 2 \times ( 2 m )$$
where t1 is the thickness of the auxiliary layer, t2 is the thickness of the bank, λ is a target wavelength of the emissive area, and m is an integer.

12. The display device of claim 4, wherein the reflective electrode is disposed in the emissive area and the non-emissive area, and
wherein the display device further comprises a transistor between the substrate and the reflective electrode in the non-emissive area.

13. The display device of claim 12, wherein the reflective electrode is connected to the transistor in the non-emissive area.

14. The display device of claim 12, wherein the auxiliary layer overlaps the transistor.

15. The display device of claim 14, wherein the auxiliary layer partially exposes an upper surface of the reflective electrode, and the anode electrode connects to the exposed upper surface of the reflective electrode.

16. The display device of claim 1, further comprising a bank disposed in the non-emissive area,
wherein a thickness t1 of the auxiliary layer and a thickness t2 of the bank satisfy a following equation:
$$( t 1 + t 2 ) = λ / 2 \times ( 2 m )$$
where t1 is the thickness of the auxiliary layer, t2 is the thickness of the bank, λ is a target wavelength of the emissive area, and m is an integer.
